(19) United States
(12) Patent Application Publication
(10) Pub. No.: US 2005/0064714 A1
(43) Pub. Date: Mar. 24, 2005

(54) Method for controlling critical dimensions during an etch process

(75) Inventors: David Mui, Fremont, CA (US); Wei Liu, San Jose, CA (US); Hiroki Sasano, Sunnyvale, CA (US); Kyeongran Yoo, Palo Alto, CA (US)

Correspondence Address: MOSER, PATTERSON & SHERIDAN, LLP;APPLIED MATERIALS INC, 595 SHREWSBURY AVE, SUITE 100, SHREWSBURY, NJ, 07702, US

(73) Assignee: Applied Materials, Inc.

(21) Appl. No.: 10/666,317

(22) Filed: Sep. 19, 2003

(51) Int. Cl. H01L 21/302; H01L 21/461

(52) U.S. Cl. 438/706

(57) ABSTRACT

A method for controlling dimensions of structures formed on a substrate using an etch process includes measuring pre-etch dimensions of the respective elements of a patterned etch mask and adjusting a process recipe of the etch process using the results of the pre-etch measurements. In one application, the method is used to control critical dimensions of a gate structure of a field effect transistor.

### BACKGROUND OF THE INVENTION

1. Field of the Invention

The present invention generally relates to semiconductor substrate processing systems. More specifically, the present invention relates to a method for controlling etch processes in a semiconductor substrate processing system.

2. Description of the Related Art

Fabrication of electronic semiconductor devices comprises processes in which one or more layers of a film stack of the device are partially removed using an etch process. One method of fabricating such devices comprises forming a patterned mask (e.g., hard mask or photoresist mask) on the film stack and then etching the underlying layer(s) using the patterned mask as an etch mask.

The patterned mask generally includes elements having topographic dimensions that correspond to structures that are to be etched in the underlying layer(s). Manufacturing variables for processes of patterning the etch mask may result in a broad statistical distribution (i.e., large σ (sigma), where σ is a standard deviation) for the dimensions of the elements of the etch masks within a group (i.e., batch) of substrates.

One method of controlling dimensions for the etched structures to be formed on the substrates comprises measuring the smallest widths (i.e., critical dimensions, or CDs) of the respective elements of the etch masks, as well as the etched structures, statistically processing the results of such measurements, and adjusting the etch process performed on subsequent batches of the substrates.

Unfortunately, this method does not compensate for substrate-to-substrate variations of the critical dimensions (CDs) within a batch of substrates. Variables inherent to the etch process combined with the variables of the etch mask patterning process may broaden distribution for the critical dimensions of etched structures. This means that the post-etch statistical distribution of the critical dimensions for etched structures may be broader than the pre-etch distribution of critical dimensions for the elements of the etch mask. As such, some etched structures may have critical dimensions outside a pre-determined range of acceptable values.

Therefore, there is a need in the art for an improved method for controlling critical dimensions of structures formed on a substrate using an etch process in a semiconductor substrate processing system.

### SUMMARY OF THE INVENTION

The present invention is a method for controlling dimensions of structures formed on a substrate using an etch process. In one embodiment, the method comprises measuring dimensions (e.g., critical dimensions (CD)) of elements of a patterned etch mask and adjusting etch process parameters (e.g., time) based on such measurements. In one application, the method facilitates control of critical dimensions for a gate structure of a field effect transistor using optical metrology and etch modules of an integrated substrate processing system.

### BRIEF DESCRIPTION OF THE DRAWINGS

The teachings of the present invention can be readily understood by considering the following detailed description in conjunction with the accompanying drawings, in which:

FIG. 1 depicts a schematic diagram of an exemplary integrated semiconductor substrate processing system of the kind used in one embodiment of the inventive method;

FIG. 2 depicts a flow diagram of a method for controlling dimensions of etched structures formed in accordance with one embodiment of the present invention;

FIGS. 3A-3B depict a series of schematic, cross-sectional views of a substrate having a gate structure of a field effect transistor being formed in accordance with the method of FIG. 2;

FIGS. 4A-4B depict a series of exemplary diagrams showing the results of critical dimension measurements for respective elements the etch mask and the gate structure of FIGS. 3A-3B;

FIG. 5 depicts a graphical illustration of an exemplary procedure for calculating an adjustment for etch process parameters in accordance with one embodiment of the method of FIG. 2; and

FIG. 6 depicts a schematic diagram of an exemplary plasma etch processing apparatus of the kind used in performing portions of the inventive method.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method for controlling dimensions of structures formed on a substrate (e.g., semiconductor wafer, and the like) using an etch process. The method is generally used during fabrication of ultra-large-scale integrated (ULSI) semiconductor devices and circuits. In one embodiment, the method is performed using a substrate processing system that includes a metrology module configured for measuring topographic dimensions of both etched structures as well as elements of the etch masks.

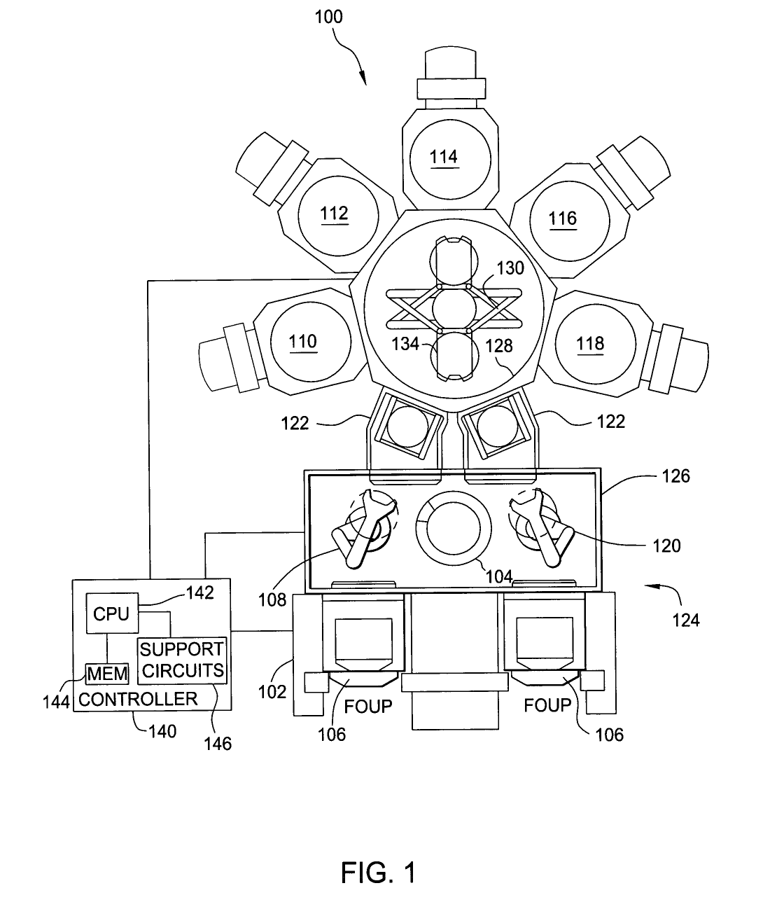

FIG. 1 depicts a schematic diagram of a semiconductor wafer processing system 100 that may illustratively be used to practice the invention. One processing system suitable for practicing the invention is a TRANSFORMA™ processing system, available from Applied Materials, Inc. of Santa Clara, Calif. A similar processing system is disclosed in commonly assigned U.S. Pat. No. 6,486,492 B1, issued Nov. 26, 2002, as well as U.S. Pat. No. 6, 150,664, issued Nov. 21, 2000, which are incorporated herein by reference. Herein the particular embodiment of the system 100 is provided for illustrative purposes and should not be used to limit the scope of the invention.

The system 100 generally includes a central transfer chamber or “mainframe” 128, such as the CENTURA® processing system for mounting a plurality of process modules 110, 112, 114, 116, 118, and at least one load-lock chamber, shown as two load-lock chambers 122 in FIG. 1. A transfer robot 130 is disposed within the mainframe 128 to transfer substrates between the process modules 110, 112, 114, 116, and 118. A factory interface 124 having at least one metrology module 126 and an input/output module 102 is coupled to the load-lock chambers 122. The input/output module 102 has at least one front opening unified pod (FOUP), depicted in FIG. 1 as two FOUPs 106. The metrology module 126 is coupled to a system controller 140 and provides for high-speed data collection of critical dimensions of structures formed on wafers entering and/or leaving the system 100.

The metrology module 126 comprises an optical measuring tool 104 and two substrate robots 108 and 120 that transfer pre-processed and post-processed substrates between the FOUPs 106, optical measuring tool 104, and load-lock chambers 122. One optical measuring tool suitable for use in this system is available from Nanometrics Incorporated, located in Milpitas, Calif.

The system controller 140 is coupled to and controls each module of the integrated processing system 100. The system controller 140 controls all aspects of operation of the system 100 using a direct control of modules and apparatus of the system 100 or, alternatively, by controlling the computers (or controllers) associated with these modules and apparatus. In operation, the system controller 140 enables feedback from the respective modules and apparatus to optimize substrate throughput.

The system controller 140 generally comprises a central processing unit (CPU) 142, a memory 144, and support circuits 146. The CPU 142 may be one of any form of a general purpose computer processor that can be used in an industrial setting. The support circuits 146 are conventionally coupled to the CPU 142 and may comprise cache, clock circuits, input/output subsystems, power supplies, and the like. The software routines, when executed by the CPU 142, transform the CPU into a specific purpose computer (controller) 140. The software routines may also be stored and/or executed by a second controller (not shown) that is located remotely from the system 100.

At least one of the process modules 110, 112, 114, 116, 118 of the system 100 may be a plasma etch module (e.g., DPS II etch module) used to perform portions of the present invention. Other processing modules may include other types of processing equipment, for example, one of the processing modules 110, 112, 114, 116, 118 may be a PRECLEAN II™ plasma cleaning module, an AXIOM® remote plasma module, a RADIANCE™ thermal processing module (these process modules are all available from Applied Materials, Inc.), among others.

One example of a possible configuration of the system 100 for performing processes in accordance with the present invention includes two load-lock chambers 122, DPS II modules 114, 116, and 118, AXIOM® modules 110 and 114, the metrology module 126 having the optical measuring tool 104 and robots 108 and 120, as well as the input/output module 102 comprising two FOUPs 106.

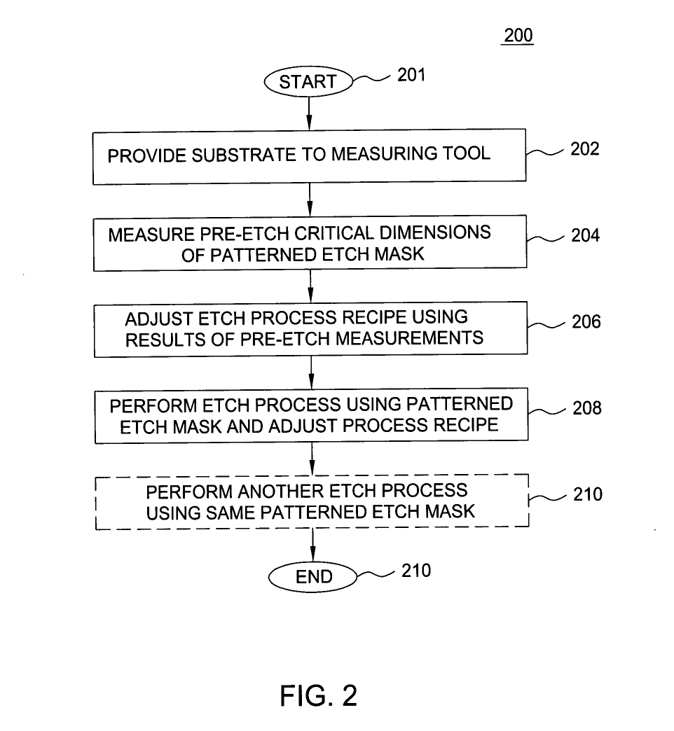

FIG. 2 depicts a flow diagram of one embodiment of the inventive method for controlling dimensions of structures formed on a substrate using an etch process as sequence 200. The sequence 200 includes the processes that are performed upon a film stack formed on the substrate. To facilitate understanding of the method, occasional reference is made to components of the integrated semiconductor wafer processing system 100 described in FIG. 1 above.

The sequence 200 starts at step 201 and proceeds to step 202. At step 202, a substrate having a patterned etch mask is provided to a measuring tool configured to measure topographic dimensions of elements of the patterned masks using a non-destructive measuring technique. The patterned etch mask is generally formed upon an underlying film stack that comprises at least one material layer. Such material layers may be formed from conductive, dielectric, and semiconductor materials or a combination thereof. Generally, the same measuring tool can also measure topographic dimensions of structures formed in the layer(s) of the film stack (discussed below in reference to step 208).

The optical measuring tool 104 may be configured for measuring topographic dimensions and thickness of thin films on a substrate using one or more non-destructive optical measuring techniques, such as spectroscopy, interferometry, scatterometry, reflectometry, ellipsometry, and the like. In one exemplary embodiment, the optical measuring tool 104 is configured to use a scatterometric measuring technique.

At step 204, the smallest widths (i.e., critical dimensions, or CDs) for elements of the patterned etch mask are measured with the measuring tool utilizing a non-destructive measuring technique. The measurements of the critical dimensions of the elements of the patterned mask are generally performed in a statistically significant number of regions (e.g., 5 to 9 or more regions) of the substrate. The results of these measurements (i.e., pre-etch measurements) may be mathematically processed (e.g., averaged) for the etch mask being measured. In one exemplary embodiment, the measurements are performed using the optical measuring tool 104.

At step 206, a conventional etch process recipe that may be used to etch structures in the substrate using the patterned mask as an etch mask is adjusted. The conventional (i.e., unadjusted) etch process recipe is defined for the substrates where the patterned etch masks comprise elements having nominal critical dimensions. The adjustment for the conventional etch process recipe is calculated using the results of measurements performed during step 204.

More specifically, step 206 defines the etch process recipe adjustment that compensates for a difference (i.e., deviation) between the actual critical dimensions of the respective elements of the patterned etch mask and the nominal (e.g., mean) critical dimensions of such elements. Generally, the nominal critical dimensions are defined as mean (e.g., root-mean-square, arithmetic mean, and the like) critical dimensions for the elements of the etch masks after the patterning process was performed on a batch of the substrates.

The adjusted etch process recipe is insensitive to the manufacturing variables of the process used for patterning the etch masks. As such, the structures etched on a substrate using such process may have narrow post-etch statistical distribution (i.e., small σ (sigma), where σ is a standard deviation) for the critical dimensions. Moreover, such distribution for the critical dimensions of the etched structures may also be narrower than the statistical distribution for the critical dimensions of the respective elements on the patterned etch mask.

In one embodiment, step 206 calculates the adjustment comprising corrective factors for at least one parameter related to a lateral (i.e., horizontal) etch rate of the etch process. Such parameter(s) may include a duration of time for overetching the structures being formed, etch process parameters (e.g., a flow rate and/or pressure of an etchant gas or gases, plasma source power, substrate bias power, and the like), chemical composition of the material and thickness of sidewalls of the structures, and the like.

Generally, the etch process comprises a first period (i.e., etch period) when the etched layer is being removed in the region exposed by the patterned etch mask and a second period (i.e., overetch period) when a layer disposed beneath the etched layer is partially etched. During the overetch period, any remaining traces of the material of the etched layer are removed from a surface of the underlying layer. Generally, a duration of the overetch period is about 0 to 100% of the duration of the etch period.

The overetch period may be characterized by a rate of removal the underlying layer (i.e., vertical etch rate), as well as by a rate of lateral etching (i.e., horizontal etch rate) for the sidewalls of the remaining portion of the layer that was etched during the first period of the etch process. In one exemplary embodiment, to compensate for deviation of the critical dimensions of the patterned etch mask from the nominal values for such dimensions, step 206 calculates the adjustment that modifies a duration for the overetch period.

At step 208, the sequence 200 performs the etch process that etches one or more material layers of the film stack beneath the patterned mask using the adjusted etch process recipe to form the etched structures in the layer(s) of the film stack. In one exemplary embodiment, the duration of the overetch period of the etch process is adjusted to compensate for manufacturing variables of the process for patterning the etch masks. Such adjusted etch process provides a small post-etch standard deviation (i.e., narrow statistical distribution) for the critical dimensions of the etched structures. Generally, such standard deviation, as well as standard deviation of the post-etch critical dimensions of the respective elements of the patterned etch mask, is smaller than the pre-etch standard deviation of the critical dimensions of the elements of the etch mask. In one exemplary embodiment, the post-etch measurements may be performed using the measuring tool and methodology which are described above in reference to step 204.

At step 210, other in-situ or ex-situ etch processes may optionally be performed on the film stack using the same patterned etch mask.

At step 212, the sequence 200 ends.

In one illustrative application, a gate conductor layer of a gate structure of a field effect transistor, such as a complementary metal-oxide-semiconductor (CMOS) field effect transistor, and the like, is etched using the sequence 200.

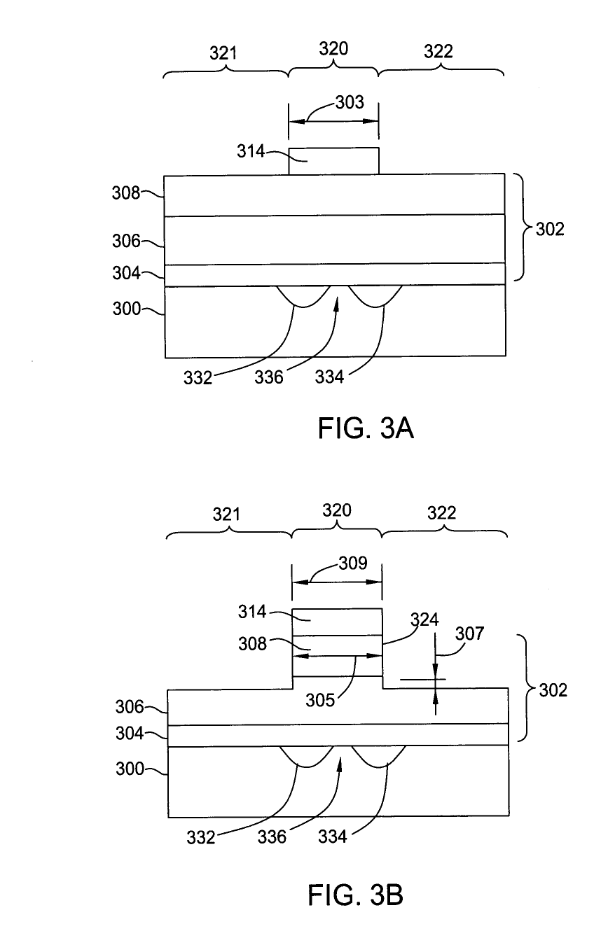

FIGS. 3A-3B depict a series of schematic, cross-sectional views of a substrate having a gate structure of a field effect transistor being fabricated, wherein critical dimensions for the gate conductor layer of a gate electrode of the gate structure are controlled using process steps of the sequence 200 which are illustratively performed by the modules of the processing system 100. The cross-sectional views in FIGS. 3A-3B are not depicted to scale and are simplified for illustrative purposes. To best understand the invention, the reader should simultaneously refer to FIG. 2 and FIGS. 3A-3B.

Referring to FIG. 3A, at step 202, a substrate 300 (e.g., silicon (Si) wafer, and the like) is transported to the metrology module 126 of the processing system 100. The substrate 300 generally comprises regions 332 and regions 334 (both regions are depicted using broken lines) where the sources and drains will be formed using an ion implant process after fabrication of the gate structure is completed, a film stack 302 for forming a gate structure of the transistor being fabricated, and a patterned mask 314. The source and drain regions 332, 334 are separated by a channel region 336 in each of the transistors being manufactured. In one embodiment, the film stack 302 comprises a gate dielectric layer 304, a gate electrode layer 306, and a gate conductor layer 308. The patterned mask 314 protects region 320 above the channel region 336 and portions of the wells 332 and 334, and exposes adjacent regions 321 and 322 of the substrate 300.

The patterned mask 314 is used as an etch mask for etching the layers of the film stack 302. The patterned mask 314 may comprise, for example, silicon oxynitride (SiON), silicon dioxide (SiO₂), silicon nitride (Si₃N₄), hafnium dioxide (HfO₂), Advanced Patterning Film™ (APF) available from Applied Materials, Inc. of Santa Clara, Calif., photoresist, and the like. The APF generally comprises films of SiON and α-carbon. Processes of forming such etch masks are well known in the art. In one exemplary embodiment, the patterned mask 314 is a hard mask formed of silicon oxynitride.

In one exemplary embodiment, the gate electrode layer 306 is formed of doped polysilicon (Si) and the gate dielectric layer 304 is formed of silicon dioxide (SiO₂). Generally, the layers 306 and 304 have a thickness of about 500 to 6000 Angstroms and about 10 to 60 Angstroms, respectively. Alternatively, the gate dielectric layer 304 may comprise a high-K dielectric material having a dielectric constant greater than 4.0, such as hafnium dioxide (HfO₂), hafnium silicon dioxide (HfSiO₂), and the like.

The gate conductor layer 308 is generally formed from a silicide of a metal providing an electrical interface between the gate electrode of the transistor being fabricated and elements of an interconnect network (not shown) of the semiconductor device. In one exemplary embodiment, the gate conductor layer 308 comprises tungsten silicide (WSi) and is formed to a thickness of about 300 to 2000 Angstroms.

The film stack 302 may also comprise layers formed of other materials having different thicknesses. The layers of the film stack 302 may be formed using any conventional deposition technique, such as atomic layer deposition (ALD), physical vapor deposition (PVD), chemical vapor deposition (CVD), plasma enhanced CVD (PECVD), and the like. Fabrication of the field effect transistor may be performed using the respective process modules of CENTURA®, ENDURA®, and other semiconductor wafer processing systems available from Applied Materials, Inc. of Santa Clara, Calif.

At step 204, a width 303 (e.g., about 30 to 180 nm) of the patterned mask 314 is measured in a statistically significant number of regions on the substrate 300 using the optical measuring tool 104, and the results of these measurements are averaged for the substrate 300. Generally, such pre-etch statistical distribution of the widths 303 within a batch of the substrates 300 has a standard deviation (i.e., σ (sigma)) of about 3 nm.

At step 206, an adjustment to the process recipe for etching the gate conductor layer 308 (e.g., WSi) is calculated using the results of the measured width 303 for the patterned mask 314. In one exemplary embodiment, the adjustment comprises a corrective factor related to a duration for the overetch period. If the width 303 is greater than a nominal width for the patterned mask 314, the adjustment increases a duration of time when the etch process overetches the layer 308. Correspondingly, if the width 303 is smaller than the nominal width, the adjustment decreases the duration of time when the etch process overetches the layer 308. In this embodiment, the nominal width of the patterned mask 314 is illustratively defined as a root-mean-square width of the mask 314 for substrates 300 of a batch of the substrates after the process of patterning the mask 314. Alternatively, the adjustment may comprise a corrective factor related to other parameters of the etch process, such as a flow rate and/or pressure of the etchant gas or gases, plasma source power, substrate bias power, and the like.

Referring to FIG. 3B, at step 208, the gate conductor layer 308 (e.g., WSi) is etched and removed in the regions 321 and 322 using the adjusted etch process recipe. The etch process comprises a first period (i.e., etch period) and a second period (i.e., overetch period). During the first period, the gate conductor layer 308 is etched and mostly removed from the polysilicon gate electrode layer 306. During the second period, any traces of tungsten silicide are removed from the gate electrode layer 306, as well as sidewalls 324 of the layer 308 are laterally etched and the gate electrode layer 306 is contemporaneously etched to a depth 307.

In the adjusted etch process recipe (discussed in reference to step 206 above), the duration of the overetch period is specifically defined such that the sidewalls 324 of the gate conductor layer 308 are etched to a pre-defined width 305. Generally, during the overetch period, the polysilicon gate electrode layer 306 is etched to a depth 307 of not greater than about 0 to 200 Angstroms.

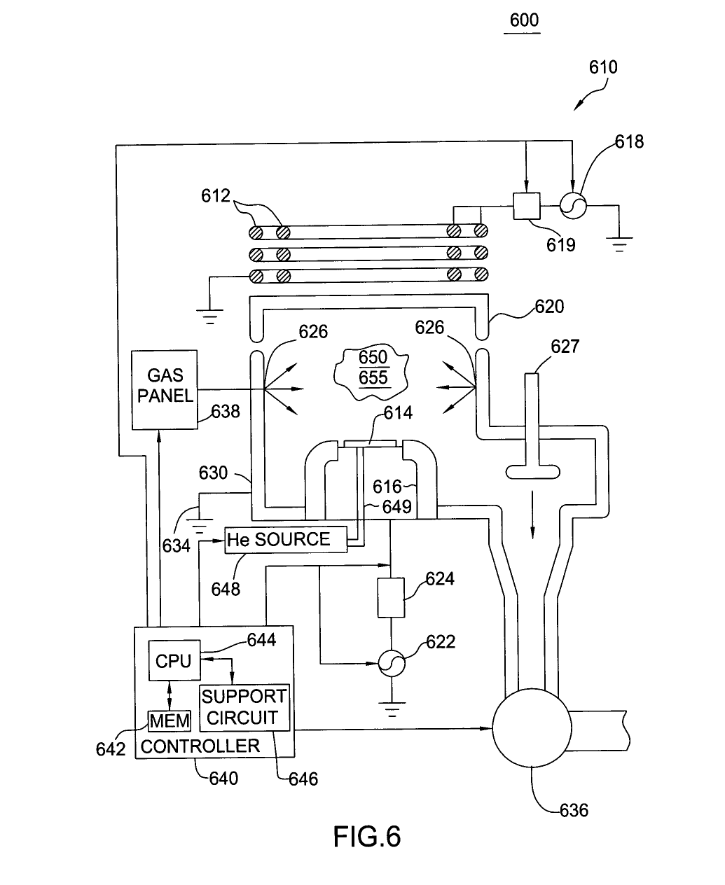

In one exemplary embodiment, step 208 performs a plasma etch process to etch layer 308 (e.g., WSi) using a gas mixture comprising nitrogen trifluoride (NF₃), chlorine (Cl₂), nitrogen (N₂), and oxygen (O₂). The etch process may be performed using, for example, the Decoupled Plasma Source (DPS) II module of the CENTURA® processing system. The DPS II module (discussed in reference to FIG. 6 below) is a plasma etch reactor that uses an inductive source (i.e., antenna) to produce a high-density plasma. The DPS II module may also control a substrate temperature in a range from about 20 to 350 degrees Celsius. To determine the endpoint of an etch process or a particular period of the etch process, the DPS II module may use an endpoint detection system to monitor plasma emissions at a particular wavelength, control of process time, laser interferometry, and the like.

In one illustrative embodiment, during the first period, the gate conductor layer 308 comprising tungsten suicide is etched using the DPS II module by providing nitrogen trifluoride (NF₃) at a flow rate 0 to 40 sccm, chlorine (Cl₂) at a flow rate of 0 to 100 sccm (i.e., a NF₃:Cl₂ flow ratio ranging from 100% NF₃ to 100% Cl₂), nitrogen (N₂) at a flow rate of 0 to 200 sccm, oxygen (O₂) at a flow rate of 0 to 40 sccm, applying power to an inductively coupled antenna between 0 and 1500 W, applying a cathode bias power between 0 and 200 W, and maintaining a wafer pedestal temperature between 20 and 80 degrees Celsius and a chamber pressure between 2 and 10 mTorr. One illustrative process provides NF₃ at a flow rate of 10 sccm, Cl₂ at a flow rate of 40 sccm (i.e., a NF₃:Cl₂ flow ratio of about 1:4), N₂ at a flow rate of 80 sccm, O₂ at a flow rate of 10 sccm, applies 750 W of power to the inductively coupled antenna, 100 W of cathode bias power, maintains a wafer pedestal temperature of 65 degrees Celsius and a chamber pressure of 4 mTorr. Such etch process provides etch selectivity for tungsten silicide (layer 308) over silicon oxynitride (mask 314) of at least 4:1, as well as etch selectivity for silicon oxynitride over polysilicon (layer 306) of about 5:1.

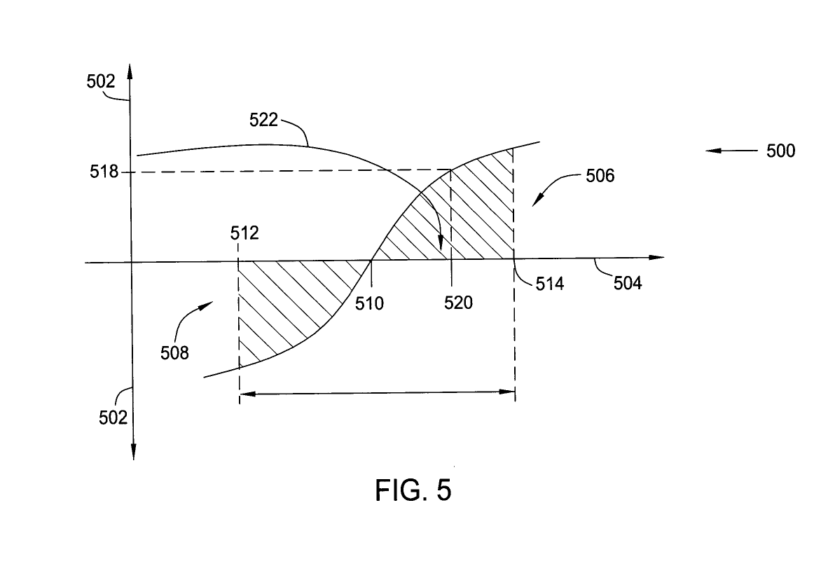

In this embodiment, the second period of step 208 is a continuation of the first period. During the second period, the gate conductor layer 308 comprising tungsten silicide is overetched, as well as the polysilicon gate electrode layer 306 is etched to the depth 307, using the same etch parameters as the first period. A nominal duration (duration 510 in FIG. 5 below) of the second period is about 50% of the duration of the first period.

Such etch process provides post-etch standard deviation for the width 305 of the gate conductor layer 308 on the substrates 300 of a batch of the substrates of about 0.5 to 2 nm. Additionally, the etch process reduces the post-etch standard deviation for the widths 309 of the patterned mask 314 to about 0.5 to 2 nm, thus facilitating small standard deviation for subsequent etch processes (e.g., etching the gate electrode layer 306) that may use the patterned mask 314 as an etch mask (e.g., step 210). The post-etch measurements of the widths 305 and 309 may be performed using the optical measuring tool 104 and methodology described above in reference to step 204.

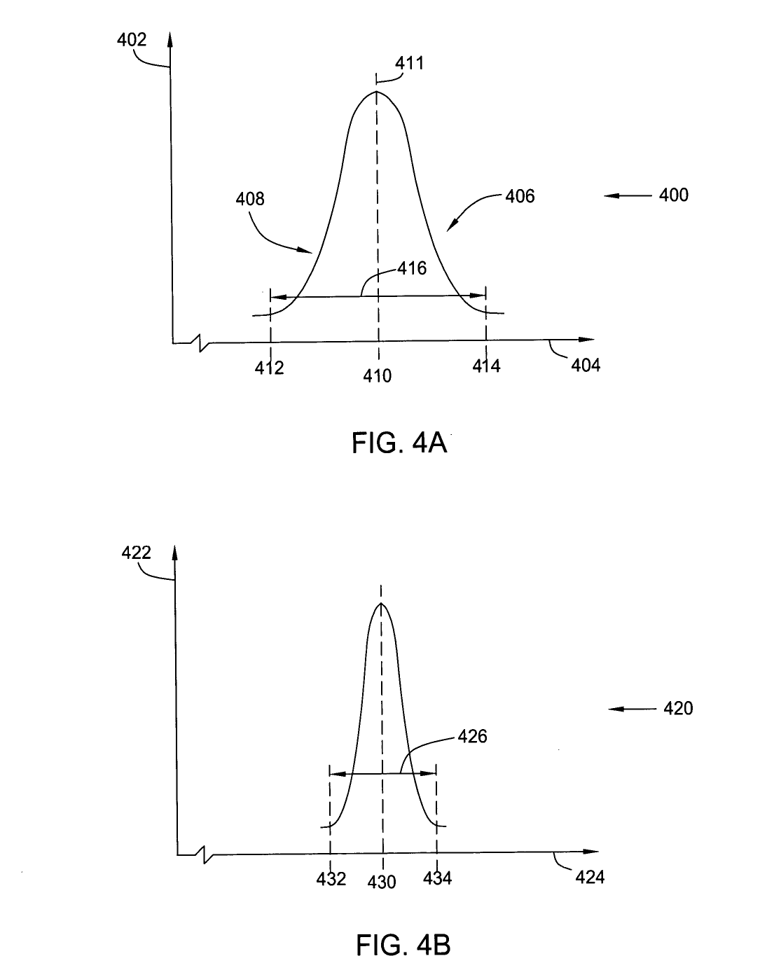

FIGS. 4A-4B depict a series of exemplary diagrams illustrating results for the pre-etch and post-etch measurements performed on a batch of the substrates 300. The measurements are performed using the optical measuring tool 104 of the TRANSFORMA™ processing system 100.

In FIG. 4A, a graph 400 depicts an exemplary pre-etch statistical distribution (y-axis 402) of the width 303 of the patterned masks 314 for substrates 300 of a batch of the substrates. The distribution 402 has a width 416 (e.g., 6σ, or about 99.5% of the substrates), where a center 410 of the distribution relates to the nominal value of the width 303 of the patterned masks 314. Boundaries 412 and 414 for the distribution 402 illustratively correspond to the minimal and maximal values for the width 303 on the substrates 300 and limit the distribution to a ±3σ range around the center 410, respectively. A portion 406 of the distribution 402 above the centerline 411 relates to the substrates 300 having widths 314 that are greater than the nominal width 416. Accordingly, a portion 408 of the distribution 400 below the centerline 411 relates to the substrates 300 having widths 314 that are smaller than the nominal width 410. In one exemplary embodiment, the values 416, 410, 412, and 414 were 20, 90, 80, and 100 nm, respectively.

In FIG. 4B, a graph 420 depicts an exemplary post-etch statistical distribution 422 of the width 305 of the gate conductor layer 308 of the substrates 300 of the same batch of the substrates after the adjusted etch process of 208. The distribution 422 has a width 426 (e.g., 6σ, or about 99.5% of the substrates), where a center 430 of the distribution relates to the nominal value of the width 305 of the gate conductor layer 308. Boundaries 432 and 434 of the distribution 422 illustratively correspond to the minimal and maximal values of the width 305 for the substrates 300 and limit the distribution to a ±3σ range around the center 430, respectively. In one exemplary embodiment, the values 426, 430, 432, and 434 were 5, 90, 87.5, and 92.5 nm, respectively.

As such, the inventive method produced etched structures in the gate conductor layer 308 which have approximately 4 times narrower post-etch statistical distribution 422 for the critical dimensions (i.e., width 305) than the pre-etch statistical distribution 402 for the critical dimensions (i.e., width 303) of the respective elements of the patterned etch mask 314. Additionally, the statistical distribution for the post-etch width 309 of the patterned etch mask 314 is similarly narrowed.

FIG. 5 depicts a graphical illustration for an exemplary procedure that may be used to calculate an adjustment for the etch process recipe of step 208 in accordance with one embodiment of the method of FIG. 2. Graph 500 generally depicts a deviation (y-axis 502) of the width 303 of the patterned mask 314 versus a duration (x-axis 504) of the second period (i.e., overetch period) for the adjusted etch process performed on the gate conductor layer 308. Due to dependence of the lateral etch rate on process time, the graph 500 is generally a non-linear curve.

The duration of the overetch period is expressed using units for deviation of the width 303 from the nominal value 410 (discussed in reference to FIG. 4A above). More specifically, a nominal duration 510 of the second period relates to the patterned mask 314 having the nominal value 410 (i.e., when the deviation of the width 303 is equal to 0). In FIG. 5, the portions 508 and 506 of the graph 500 relate to the portions 408 and 406 in the graph 402 (FIG. 4A), respectively. Accordingly, durations 510, 512, and 514 of the overetch period correspond to the patterned masks 314 having, respectively, values 410, 412, and 414 for the width 303. Using the graph 500, a duration 520 for the overetch period that corresponds to the patterned mask 314 having a deviation 518 from the nominal width 410 may be defined as shown with arrow 522.

FIG. 6 depicts a schematic diagram of the Decoupled Plasma Source (DPS II) etch reactor 600 that illustratively may be used to practice portions of the invention. The DPS II reactor is generally used as a processing module of the CENTURA® integrated semiconductor wafer processing system. The reactor 600 comprises a process chamber 610 having a wafer support pedestal 616 within a conductive chamber body 630, and a controller 640.

The chamber 610 is supplied with a substantially flat dielectric ceiling 620. Other modifications of the chamber 610 may have other types of ceilings, e.g., a dome-shaped ceiling. Above the ceiling 620 is disposed an antenna comprising at least one inductive coil element 612 (two co-axial elements 612 are shown). The inductive coil element 612 is coupled, through a first matching network 619, to a plasma power source 618. The plasma source 618 typically is capable of producing up to 3000 W at a tunable frequency in a range from 50 kHz to 13.56 MHz.

The support pedestal (cathode) 616 is coupled, through a second matching network 624, to a biasing power source 622. The biasing source 622 generally is a source of up to 500 W at a frequency of approximately 13.56 MHz that is capable of producing either continuous or pulsed power. In other embodiments, the source 622 may be a DC or pulsed DC source.

A controller 640 comprises a central processing unit (CPU) 644, a memory 642, and support circuits 646 for the CPU 644 and facilitates control of the components of the DPS II etch process chamber 610 and, as such, of the etch process, as discussed below in further detail.

In operation, a semiconductor wafer 614 is placed on the pedestal 616 and process gases are supplied from a gas panel 638 through entry ports 626 to form a gaseous mixture 650. The gaseous mixture 650 is ignited into a plasma 655 in the chamber 610 by applying power from the plasma and bias sources 618 and 622 to the inductive coil element 612 and the support pedestal 616, respectively. The pressure within the interior of the chamber 610 is controlled using a throttle valve 627 and a vacuum pump 636. Typically, the conductive chamber body 630 is coupled to an electrical ground 634. The temperature of the conductive chamber body 630 is controlled using liquid-containing conduits (not shown) that run through the conductive chamber body 630.

The temperature of the wafer 614 is controlled by stabilizing a temperature of the support pedestal 616. In one embodiment, the helium gas from a gas source 648 is provided via a gas conduit 649 to channels (not shown) formed in the pedestal surface under the wafer 614. The helium gas is used to facilitate heat transfer between the pedestal 616 and the wafer 614. During the processing, the pedestal 616 may be heated by a resistive heater (not shown) within the pedestal to a steady state temperature and then the helium gas facilitates uniform heating of the wafer 614. Using such thermal control, the wafer 614 is maintained at a temperature of between about 20 and 350 degrees Celsius.

Those skilled in the art will understand that other forms of etch chambers may be used to practice the invention, including chambers with remote plasma sources, electron cyclotron resonance (ECR) plasma chambers, and the like.

To facilitate control of the process chamber 610 as described above, the controller 640 may be one of any form of general-purpose computer processor that can be used in an industrial setting for controlling various chambers and sub-processors. The memory, or computer-readable medium, 642 of the CPU 644 may be one or more of readily available memory such as random access memory (RAM), read only memory (ROM), floppy disk, hard disk, or any other form of digital storage, local or remote. The support circuits 646 are coupled to the CPU 644 for supporting the processor in a conventional manner. These circuits include cache, power supplies, clock circuits, input/output circuitry and subsystems, and the like. The inventive method is generally stored in the memory 642 as a software routine. The software routine may also be stored and/or executed by a second CPU (not shown) that is remotely located from the hardware being controlled by the CPU 644.

The invention may be practiced using other etch processes wherein parameters may be adjusted to achieve acceptable characteristics by those skilled in the art by utilizing the teachings disclosed herein without departing from the spirit of the invention. Although the forgoing discussion referred to fabrication of a field effect transistor, fabrication of the other devices and structures used in the integrated circuits can also benefit from the invention.

While the foregoing is directed to the illustrative embodiment of the present invention, other and further embodiments of the invention may be devised without departing from the basic scope thereof, and the scope thereof is determined by the claims that follow.

1. A method for controlling dimensions of structures formed on a substrate using an etch process, comprising:
providing the substrate having a patterned etch mask formed thereon;
measuring dimensions of elements of the mask on the substrate;
adjusting a process recipe for an etch process using the results of measuring said dimensions; and
forming the structures on the substrate performing the etch process that uses the adjusted process recipe.

2. The method of claim 1 wherein the substrate is a semiconductor wafer.

3. The method of claim 1 wherein the mask is a patterned hard etch mask or a patterned photoresist mask.

4. The method of claim 1 wherein the structures are formed in at least one material layer disposed beneath the mask.

5. The method of claim 1 wherein the dimensions are smallest widths of the elements.

6. The method of claim 1 wherein the dimensions are measured using a non-destructive measuring technique.

7. The method of claim 6 wherein the measuring technique is an optical measuring technique.

8. The method of claim 1 wherein the measuring step and the forming step are performed using processing modules of a single substrate processing system.

9. The method of claim 1 wherein the adjusting step comprises calculating an adjustment for the process recipe of the etch process.

10. The method of claim 9 wherein the adjustment is an adjustment for at least one parameter related to a thickness of a film of the material removed from sidewalls of the structures during the etch process.

11. The method of claim 10 wherein the at least one parameter is selected from a group consisting of a duration of time for overetching the structures, a flow rate and/or pressure of an etchant gas or gases, a plasma source power, a substrate bias power, a material of the structures and a thickness of sidewalls of the structures.

12. A method for controlling dimensions a gate structure of a field effect transistor formed on a substrate using an etch process, comprising:
providing the substrate having a patterned etch mask formed upon a film stack of the gate structure;
measuring dimensions of elements of the mask on the substrate;
adjusting a process recipe for an etch process of etching a layer of the film stack using the results of measuring said dimensions; and
forming the structures in the layer performing the etch process that uses the adjusted process recipe.

13. The method of claim 12 wherein the layer is selected from a group consisting of a gate conductor layer, a gate electrode layer, and a gate dielectric layer.

14. The method of claim 12 wherein the gate conductor layer comprises WSi, the gate electrode layer comprises doped polysilicon and the gate dielectric layer comprises SiO₂ or HfO₂.

15. The method of claim 12 wherein the mask is a patterned hard etch mask or a patterned photoresist mask.

16. The method of claim 12 wherein the mask comprises a material selected from a group consisting of SiON, SiO₂, Si₃N₄, HfO₂ and α-carbon.

17. The method of claim 12 wherein the dimensions are smallest widths of the elements.

18. The method of claim 12 wherein the dimensions are measured using a non-destructive measuring technique.

19. The method of claim 18 wherein the measuring technique is an optical measuring technique.

20. The method of claim 12 wherein the measuring step and the forming step are performed using processing modules of a single substrate processing system.

21. The method of claim 12 wherein the adjusting step comprises calculating an adjustment for the process recipe of the etch process for etching the layer.

22. The method of claim 21 wherein the adjustment is an adjustment for at least one parameter related to a thickness of a film of the material removed from sidewalls of the layer during the etch process.

23. The method of claim 22 wherein the at least one parameter is selected from a group consisting of a duration of time for overetching the structures, a flow rate and/or pressure of an etchant gas or gases, a plasma source power, a substrate bias power, a material of the structures and a thickness of sidewalls of the structures.

24. A computer-readable medium containing software that when executed by a computer causes a semiconductor wafer processing system to control dimensions of structures formed on a substrate using an etch process, said medium using a method, comprising:
providing the substrate having a patterned etch mask formed thereon;
measuring dimensions of elements of the mask on the substrate;
adjusting a process recipe for an etch process using the results of measuring said dimensions; and
forming the structures on the substrate performing the etch process that uses the adjusted process recipe.

25. The computer-readable medium of claim 24 wherein the measuring step and the forming step are performed using processing modules of a single substrate processing system.

26. The computer-readable medium of claim 24 wherein the adjusting step comprises calculating an adjustment for the process recipe of the etch process.

27. The computer-readable medium of claim 26 wherein the adjustment is an adjustment for at least one parameter related to a thickness of a film of the material removed from sidewalls of the structures during the etch process.

28. The computer-readable medium of claim 27 wherein the at least one parameter is selected from a group consisting of a duration of time for overetching the structures, a flow rate and/or pressure of an etchant gas or gases, a plasma source power, a substrate bias power, a material of the structures and a thickness of sidewalls of the structures.
